(19) United States
(12) Patent Application Publication
(10) Pub. No.: US 2025/0210448 A1
(43) Pub. Date: Jun. 26, 2025

(54) DIE ATTACH FILM AND SEMICONDUCTOR PACKAGE INCLUDING THE SAME

(71) Applicant: SAMSUNG ELECTRONICS CO., LTD., SUWON-SI (KR)

(72) Inventors: Myoungchul Eum, Suwon-si (KR); Hansol Yoo, Suwon-si (KR)

(21) Appl. No.: 18/982,738

(22) Filed: Dec. 16, 2024

(30) Foreign Application Priority Data
Dec. 21, 2023 (KR) 10-2023-0188795

(51) Int. Cl. H01L 23/373; C09J 7/10; C09J 7/38; C09J 11/04; C09K 5/14; H01L 23/00; H01L 25/07

(52) U.S. Cl. CPC H01L 23/3737; C09J 7/10; C09J 7/385; C09J 11/04; C09K 5/14; H01L 23/3732; H01L 23/3735; H01L 24/29; H01L 24/32; C09J 2203/326; C09J 2301/302; C09J 2301/408; H01L 25/074; H01L 2224/29084; H01L 2224/2919; H01L 2224/2929; H01L 2224/29324; H01L 2224/2939; H01L 2224/29393; H01L 2224/29499; H01L 2224/32145; H01L 2224/32225; H01L 2225/0651; H01L 2225/06562

(57) ABSTRACT

A die attach film including an adhesive layer, an alumina filler disposed in the adhesive layer, and a diamond filler disposed in the adhesive layer, wherein a content of the alumina filler and the diamond filler in combination is about 70 parts by weight to about 85 parts by weight based on 100 parts by weight of the adhesive layer, and a ratio of parts by weight of the alumina filler to parts by weight of the diamond filler is about 2:1 to about 3:1.

### CROSS-REFERENCE TO RELATED APPLICATION

This application is based on and claims priority under 35 USC § 119 to Korean Patent Application No. 10-2023-0188795, filed on Dec. 21, 2023, in the Korean Intellectual Property Office, the disclosure of which is incorporated by reference herein in its entirety.

### BACKGROUND

### 1. Technical Field

The inventive concept relates to a die attach film and a semiconductor package including the same, and more particularly, to a die attach film including a diamond filler and a semiconductor package including the die attach film.

### 2. Discussion of Related Art

Developments in the electronics industry have led to electronic devices becoming more compact and higher performance. Accordingly, semiconductor packages used in electronic devices have been developed to have high capacities and highly integrated structures. To improve capacity and integration of the semiconductor packages, a structure has been implemented in which a plurality of semiconductor chips are stacked. In such a semiconductor package structure, a semiconductor chip may be fixed on a package substrate or another semiconductor chip through a die attach film.

The heat accumulated in highly integrated semiconductor package structures has increased due to improved performance of the semiconductor chips. Structures for improving thermal performance of the semiconductor package may enable further improvements in integration and performance.

### SUMMARY

The inventive concept provides a die attach film with improved thermal conductivity, wherein the die attach film includes an alumina filler and a diamond filler dispersed in an adhesive layer.

The inventive concept provides a semiconductor package having improved heat dissipation characteristics and including a die attach film having improved thermal conductivity, wherein the die attach file includes an alumina filler and a diamond filler dispersed in an adhesive layer.

Aspects of the inventive concept are not limited to those mentioned above, and other aspects not mentioned will be clearly understood by those skilled in the art from the descriptions below.

According to an aspect of the inventive concept, there is provided a die attach film including an adhesive layer, an alumina filler disposed in the adhesive layer, and a diamond filler disposed in the adhesive layer, wherein a content of the alumina filler and the diamond filler in combination is about 70 parts by weight to about 85 parts by weight based on 100 parts by weight of the adhesive layer, and a ratio of parts by weight of the alumina filler to parts by weight of the diamond filler is about 2:1 to about 3:1.

According to another aspect of the inventive concept, there is provided a die attach film including a first base film, an adhesive layer disposed on the first base film, a pressure sensitive adhesive (PSA) layer disposed on the adhesive layer, and a second base film disposed on the PSA layer, wherein the adhesive layer includes a binding polymer, a thermosetting resin, a curing agent, a filler, and an additive, wherein the filler includes an alumina filler and a diamond filler, a content of the alumina filler and the diamond filler in combination is about 70 parts by weight to about 85 parts by weight based on 100 parts by weight of the adhesive layer, and a ratio of parts by weight of the alumina filler to parts by weight of the diamond filler is about 2:1 to about 3:1.

According to another aspect of the inventive concept, there is provided a semiconductor package including a substrate, a first semiconductor chip disposed on the substrate, a semiconductor chip stack disposed on the substrate to be horizontally apart from the first semiconductor chip and including a plurality of second semiconductor chips stacked in a vertical direction, a bonding wire connecting the substrate to the semiconductor chip stack, and a plurality of die attach films respectively disposed on lower surfaces of the plurality of second semiconductor chips of the semiconductor chip stack, wherein each of the plurality of die attach films includes an adhesive layer, an alumina filler dispersed in the adhesive layer, and a diamond filler dispersed in the adhesive layer, wherein a content of the alumina filler and the diamond filler in combination is about 70 parts by weight to about 85 parts by weight based on 100 parts by weight of the adhesive layer, and a ratio of parts by weight of the alumina filler to parts by weight of the diamond filler is about 2:1 to about 3:1.

### BRIEF DESCRIPTION OF THE DRAWINGS

Embodiments will be more clearly understood from the following detailed description taken in conjunction with the accompanying drawings in which:

FIG. 1 is a schematic cross-sectional view illustrating a die attach film according to an embodiment;

FIG. 2 is a conceptual diagram illustrating various materials included in an adhesive layer according to an embodiment;

FIG. 3 is a comparative graph illustrating a change in thermal conductivity according to the presence or absence of a diamond filler in a die attach film;

FIG. 4A is a schematic cross-sectional view illustrating a semiconductor package according to an embodiment;

FIG. 4B is an enlarged cross-sectional view of portion CX of the semiconductor package of FIG. 4A;

FIG. 5, FIG. 6, and FIG. 7 are schematic cross-sectional views illustrating semiconductor packages according to other embodiments;

FIG. 8 is a flowchart illustrating a method of manufacturing a semiconductor package according to an embodiment;

FIG. 9, FIG. 10, FIG. 11, FIG. 12, FIG. 13, FIG. 14, and FIG. 15 are cross-sectional views illustrating a sequential process of a method of manufacturing a semiconductor package according to an embodiment; and

FIG. 16 is a diagram schematically illustrating a configuration of a semiconductor package according to embodiments.

### DETAILED DESCRIPTION

Hereinafter, embodiments are described in detail with reference to the accompanying drawings. The same reference numerals may be used for the same components in the drawings, and redundant descriptions thereof may be omitted.

The disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the disclosure. In the disclosure, certain detailed descriptions may be omitted when they serve to obscure the essence of the inventive concept.

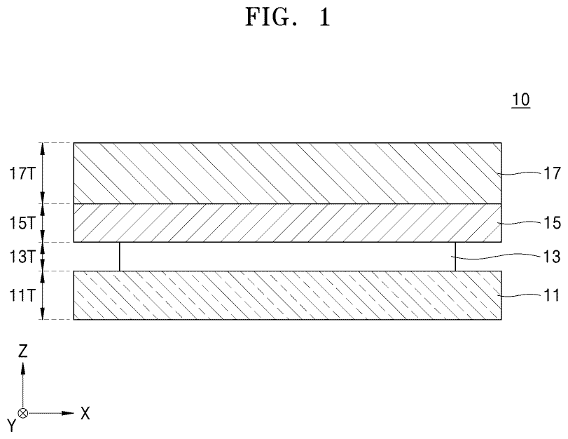

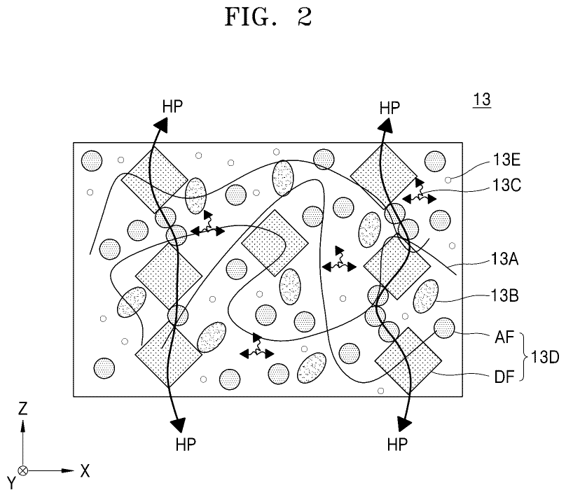

FIG. 1 is a schematic cross-sectional view illustrating a die attach film 10 according to an embodiment. FIG. 2 is a conceptual diagram illustrating various materials included in an adhesive layer 13 according to an embodiment.

Referring to FIG. 1, there is shown a cross-sectional view of the die attach film 10. The die attach film 10 may include a first base film 11, the adhesive layer 13, a pressure sensitive adhesive (PSA) layer 15, and a second base film 17. The base film 11, the adhesive layer 13, the pressure sensitive adhesive (PSA) layer 15, and the second base film 17 may be sequentially stacked.

Although there may be a difference between bonding and adhesion in a strict sense according to a dictionary definition, the term adhesion may be used herein as a comprehensive term including both bonding and adhesion. In addition, the term attachment may be used to include either bonding or adhesion.

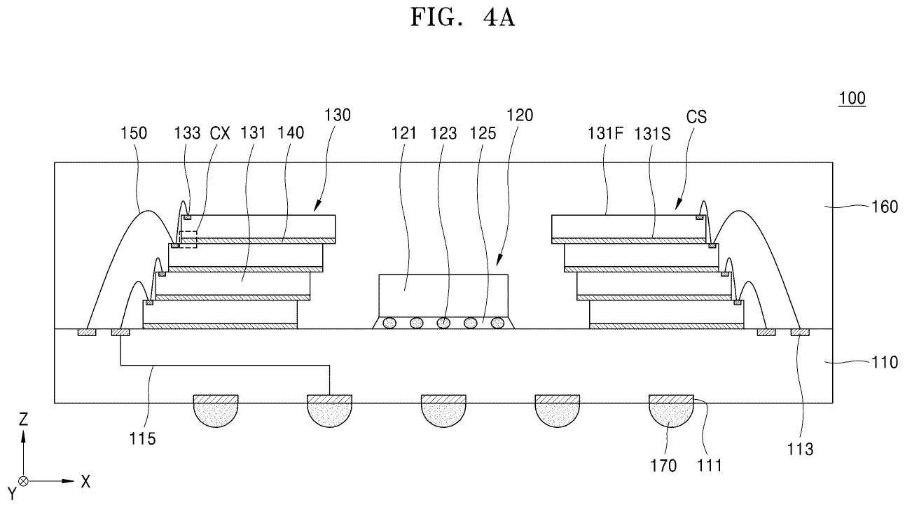

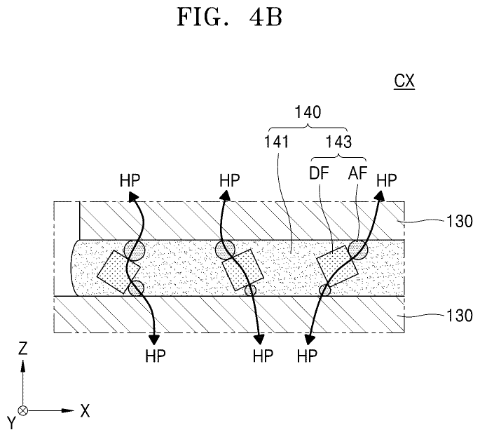

The die attach film 10 may be used as a film to bond and combine a plurality of semiconductor chips 130 (i.e., a plurality of second semiconductor chips 130) (see FIG. 4A) stacked in a vertical direction (a Z direction) with each other when manufacturing a semiconductor package (100, see FIG. 4A). In this specification, the die of the die attach film 10 may be a term referring to the semiconductor chip 130 (see FIG. 4A).

The die attach film 10 may include the first base film 11, the adhesive layer 13, the PSA layer 15, and the second base film 17. The adhesive layer 13 may serve to bond and combine the semiconductor chips 130 (see FIG. 4A) with each other. The first base film 11, the PSA layer 15, and the second base film 17 may serve to protect the adhesive layer 13. For example, the first base film 11, the PSA layer 15, and the second base film 17 may serve to protect the adhesive layer 13 until the adhesive layer 13 is attached to the semiconductor chip 130 (see FIG. 4A).

In some embodiments, a thickness 11T of the first base film 11 may be between about 35 micrometers (μm) to about 40 μm, a thickness 13T of the adhesive layer 13 may be between about 5 μm to about 100 μm, a thickness 15T of the PSA layer 15 may be between about 5 μm to about 30 μm, and a thickness 17T of the second base film 17 may be between about 80 μm to about 100 μm. Here, the thickness of each of the components may refer to a height in the vertical direction (the Z direction).

As the thickness 13T of the adhesive layer 13 of the die attach film 10 increases, a thickness of the die attach film 10 and a thickness of the semiconductor package 100 (see FIG. 4A) may increase. As the thickness 13T of the adhesive layer 13 of the die attach film 10 is decreased, heat dissipation characteristics of the adhesive layer 13, the die attach film 10 including the adhesive layer 13, and the semiconductor package 100 (see FIG. 4A) to which the die attach film 10 is applied may be impaired.

The first base film 11 may include, for example, one or more of polyethylene terephthalate (PET), polyethylene naphthalate (PEN), polyether ether ketone (PEEK), or polyimide (PI). The first base film 11 may increase physical reliability of the die attach film 10 by physically supporting the adhesive layer 13 during a manufacturing process of the semiconductor package 100 (see FIG. 4A).

The second base film 17 may include a polymer, for example, polyolefin (PO), but is not limited thereto. The second base film 17 may be, for example, a PO based PSA layer.

Referring to FIG. 2, the adhesive layer 13 may include a binding polymer 13A, a thermosetting resin 13B, a curing agent 13C, a filler 13D, and an additive 13E. In the drawing, although the binding polymer 13A is shown as a solid strand, and the thermosetting resin 13B is shown as an oval, the inventive concept is not limited thereto. The binding polymer 13A may be bonded to the thermosetting resin 13B through a curing process to form a polymer matrix forming the adhesive layer 13.

The binding polymer 13A may include a thermoplastic polymer (inclusive of resin). The thermoplastic polymer may be, for example, one or more of acrylic polymers or phenoxy polymers. The binding polymer 13A may be about 10 parts by weight with respect to 100 parts by weight of the adhesive layer.

The acrylic polymer may be an acrylic polymer. The acrylic polymer may be an acrylic polymer obtained by radical polymerization. The acrylic polymer may be an acrylic polymer obtained by radical polymerization using acrylic monomer as a raw material. Here, the acrylic monomer may include, for example, methyl (meth)acrylate, ethyl (meth)acrylate, propyl (meth)acrylate, isopropyl (meth)acrylate, butyl (meth)acrylate, isobutyl (meth)acrylate, hexyl (meth)acrylate, 2-ethylhexyl (meth)acrylate, n-octyl (meth)acrylate, isooctyl (meth)acrylate, n-nonyl (meth)acrylate, isononyl (meth)acrylate, n-decyl(meth)acrylate, isodecyl(meth)acrylate, n-dodecyl (meth)acrylate, n-tridecyl(meth)acrylate, n-tetradecyl(meth)acrylate, 2-hydroxyethyl (meth)acrylate, 2-hydroxypropyl (meth)acrylate, 4-hydroxybutyl (meth)acrylate, 6-hydroxyhexyl (meth)acrylate, 8-hydroxy octyl (meth)acrylate, 10-hydroxydecyl (meth)acrylate, 12-hydroxylauryl (meth)acrylate, (4-hydroxymethylcyclohexyl) methyl acrylate, N-methylol (meth) acrylamide, ethylene glycol di(meth)acrylate, diethylene glycol di(meth)acrylate, tetra ethylene glycol di(meth)acrylate, neopentyl glycol di(meth)acrylate, 1,6-hexanediol di(meth)acrylate, trimethylolpropane tri(meth)acrylate, pentaerythritol tri(meth)acrylate, dipentaerythritol hexa(meth)acrylate, divinylbenzene, or N,N′-methylenebisacrylamide, but is not limited thereto.

The phenoxy polymer may be a polymer. The phenoxy polymer may be a polymer obtained by polymerizing monomers, such as phenoxyethyl acrylate, phenoxyethylene glycol acrylate, phenoxypolyethylene glycol acrylate, nonyl phenoxypolyethylene glycol acrylate, nonyl phenoxypolypropylene glycol acrylate, nonyl phenoxyethylene glycol acrylate, 2-hydroxy-3-phenoxypropyl (meth)acrylate. In some embodiments, the phenoxy polymer may include poly(2,6-dilauryl-1,4-phenylenc) ether, poly(2,6-diphenyl-1,4-phenylene)ether, poly(2-methyl-6-phenyl-1,4-phenylene)ether, poly(2,6-dibenzyl-1,4-phenylene)ether, poly(2,6-dimethyl-1,4-phenylene)ether, poly(2,6-diethyl-1,4-phenylene)ether, poly(2-methyl-6-ethyl-1,4-phenylene)ether, poly(2,6-dipropyl-1,4-phenylene)ether, poly(2-ethyl-6-propyl-1,4-phenylene)ether, poly(2-methyl-1,4-phenylene)ether, poly(3-methyl-1,4-phenylene)ether, poly(2-methyl-6-allyl-1,4-phenylene)ether, poly(2,3,6-trimethyl-1,4-phenylene)ether, poly(2,3,5,6-tetramethyl-1,4-phenylene)ether, or poly(2,5-dimethyl-1,4-phenylene)ether, but is not limited thereto.

The thermosetting resin 13B may include a bifunctional thermosetting resin. The thermosetting resin 13B may include a bifunctional thermosetting resin formed of, for example, bisphenol type A, bisphenol type F, bisphenol type S, brominated bisphenol type A, hydrogenated bisphenol type A, bisphenol type AF, or biphenyl type or a multifunctional thermosetting resin.

The thermosetting resin 13B may also be one or more of epoxy-based polymers or bismaleimide-based polymers.

The epoxy polymers may include a material such as bisphenol A-type epoxy resin, bisphenol F-type epoxy resin, naphthalene-type epoxy resin, aminophenol-type epoxy resin, hydrogenated bisphenol-type epoxy resin, alicyclic epoxy resin, alcohol ether-type epoxy resin, alicyclic epoxy resin, fluorene-type epoxy resin, or a siloxane-based epoxy resin, but are not limited thereto. These materials may be used alone or in combination.

The bismaleimide-based polymer may be a polymer obtained by polymerizing a malcimide monomer containing one or two or more malcimide groups. Here, the maleimide monomer may be, for example, N-phenyl maleimide, N-(2-methylphenyl) malcimide, N-(4-methylphenyl) maleimide, N-(2,6-dimethylphenyl) maleimide, bis(4-malcimidophenyl) methane, 2,2-bis(4-(4-malcimidophenoxy)-phenyl)propane, bis(3,5-dimethyl-4-malcimidophenyl) methane, bis(3,5-diethyl-4-maleimidophenyl) methane, polyphenylmethane bismaleimide, or other malcimides containing a biphenyl structure, but is not limited thereto.

In addition, the bismaleimide-based polymer may also be obtained from a prepolymer containing a maleimide group. The prepolymer may include, for example, one or more of N-phenyl malcimide prepolymer, N-(2-methylphenyl) malcimide prepolymer, N-(4-methylphenyl) maleimide prepolymer, N-(2,6-dimethylphenyl) malcimide prepolymer, bis(4-malcimidophenyl) methane prepolymer, 2,2-bis(4-(4-malcimidophenoxy)-phenyl) propanc prepolymer, bis(3,5-dimethyl-4-maleimidophenyl) methane prepolymer, bis(3,5-diethyl-4-malcimidophenyl) methane prepolymer, polyphenyl methane bismalcimide prepolymer, maleimide prepolymer containing a biphenyl structure, prepolymer of N-phenyl malcimide and amine-based compound, prepolymer of N-(2-methylphenyl) maleimide and amine-based compound, prepolymer of N-(4-methylphenyl) malcimide and amine-based compound, prepolymer of N-(2,6-dimethylphenyl) maleimide and amine-based compound, prepolymer of bis(4-malcimidophenyl) methane and amine-based compound, prepolymer of bis(3,5-dimethyl-4-maleimidophenyl) methane and amine-based compound, prepolymer of bis(3,5-diethyl-4-maleimidophenyl) methane and amine-based compound, prepolymer of maleimide containing biphenyl structure and amine-based compound, or prepolymer of polyphenylmethane bismaleimide or amine-based compound, but is not limited thereto.

The curing agent 13C may promote curing of the adhesive layer 13 or change a curing reaction in the adhesive layer 13 at room temperature.

The curing agent 13C may include, for example, one or more of phenol novolak resin, phenol aralkyl resin, cresol novolak resin, or tert-butylphenol novolak resin.

The curing agent 13C may also include one or more materials such as acid anhydride-based curing agents, such as tetrahydrophthalic anhydride, methyl tetrahydrophthalic anhydride, methyl hexahydrophthalic anhydride, hexahydrophthalic anhydride, trialkyl tetrahydrophthalic anhydride, methyl cyclohexenedicarboxylic anhydride, phthalic anhydride, maleic anhydride, or pyromellitic anhydride; aromatic amine-based curing agents, such as metaphenylenediamine, diaminoiphenylmethane, or diaminoiphenylsulfone; aliphatic amine-based curing agents, such as diethylenetriamine or triethylenetetraamine; phenol-based curing agents, such as phenol aralkyl type phenol resin, phenol novolak type phenolic resin, xylok type phenol resin, cresol novolak type phenol resin, naphthol type phenol resin, terpene type phenol resin, multifunctional phenol resin, dicyclopentadiene type phenol resin, naphthalene type phenol resin, or novolak-type phenolic resin synthesized from bisphenol A or resol; or latent curing agents, such as dicyandiamide, but is not limited thereto. These materials may be used alone or in combination.

The additive 13E may include one or more of a curing rate controlling agent, an interfacial adhesion improver, an oxidation stabilizer, or an ion capturing agent.

Among the additives 13E, the curing rate controlling agent may include, for example, 1-methyl imidazole, 2-methyl imidazole, dimethylbenzyl imidazole, 1-decyl-2-methylimidazole, benzyldimethylamine, trimethyl amine, triethylamine, diethylaminopropylamine, pyridine, 1,8-diazabicyclo [5.4.0]undec-7-ene, 2-heptadecylimidazole, boron trifluoride monocthylamine, or 1-[3 (2-hydroxyphenyl) prop-2-enyl]imidazole (1-[3 (2-hydroxyphenyl) prop-2-enyl]imidazole), but is not limited thereto.

In an embodiment, the thermosetting resin 13B, the curing agent 13C, and the additive 13E, in combination, may be about 10 parts by weight with respect to 100 parts by weight of the adhesive layer.

In the die attach film 10 of the inventive concept, different types of fillers 13D may be disposed in the adhesive layer 13. For example, different types of fillers 13D may be dispersed in the adhesive layer 13. For example, the fillers 13D may be evenly distributed over an entire region of the adhesive layer 13.

In some embodiments, in the case of manufacturing the semiconductor package 100 (see FIG. 4A), due to the presence of the fillers 13D, even when the die attach film 10 is compressed according to the stacking of the semiconductor chips 130 (see FIG. 4A), the filler 13D may support the adhesive layer 13. For example, the filler 13D may support the adhesive layer 13 and the thickness of the die attach film 10 may be maintained at a certain level.

In some embodiments, the fillers 13D may be dispersed throughout the entire region of the adhesive layer 13, and when the adhesive layer 13 is compressed as the second semiconductor chip 130 (see FIG. 4A) is stacked to manufacture the semiconductor package 100 (see FIG. 4A), the thickness of the die attach film 10 may be maintained uniformly in the entire region of the adhesive layer 13. For example, the adhesive layer 13 may be evenly compressed and a thickness of the die attach film 10 may be uniform, such that a variation in the thickness of the die attach film 10 over its entire region may be about 0.1 μm or less.

In the die attach film 10 of the inventive concept, the filler 13D may be used as a heat transfer path HP. That is, in the die attach film 10, the filler 13D may include a material having heat dissipation characteristics. To this end, the filler 13D may include different types of fillers dispersed in the adhesive layer 13. In detail, the filler 13D may include, for example, an alumina filler AF and a diamond filler DF.

In some embodiments, the content of the filler 13D may be about 70 parts by weight to about 85 parts by weight based on 100 parts by weight of the adhesive layer 13. For example, the alumina filler AF and the diamond filler DF may be, in combination, about 80 parts by weight based on 100 parts by weight of the adhesive layer 13. In addition, in the filler 13D, a ratio of parts by weight of the alumina filler AF to parts by weight of the diamond filler DF may be about 2:1 to about 3:1. That is, the parts by weight of the alumina filler AF may be relatively greater than the parts by weight of the diamond filler DF.

Changes in thermal conductivity characteristics depending on the content of the alumina filler AF and the diamond filler DF constituting the filler 13D are described herein.

In the die attach film 10 of the inventive concept, the diamond filler DF may include a plurality of diamond grains. Each of the diamond grains may be configured as a polyhedron. The polyhedron shaped diamond grains of the diamond filler DF may be spherical polyhedrons, or approximately spherical polyhedrons. In some embodiments, the diamond grains of the diamond filler DF may have a polyhedral structure having, for example, a blocky structure, a semi-blocky structure, an angular structure, or a sharp structure. In particular, when the diamond grains of the diamond filler DF have a blocky structure or a semi-blocky structure, the thermal conductivity characteristics of the die attach film 10 may be further improved.

In the die attach film 10 of the inventive concept, the diamond filler DF may be provided in the form of powder. The powder may include the diamond grains. The powder may be dispersed in the adhesive layer 13. The diamond grains of the diamond filler DF may have a surface treated with a silane coupling agent. For example, when the diamond filler DF is provided in the adhesive layer 13 in the powder form, the diamond filler DF may not be easily mixed with other components within the adhesive layer 13 due to agglomeration. To inhibit agglomeration, the surface of the diamond grains of the diamond filler DF may be treated with the silane coupling agent, and the diamond filler DF may be dispersed in the adhesive layer 13. In some embodiments, the agglomeration of the diamond filler DF may be inhibited by increasing a surface roughness of the diamond filler DF.

In the die attach film 10 of the inventive concept, when the thickness 13T of the adhesive layer 13 is about 5 μm to about 100 μm, the diamond grains of the diamond filler DF may be formed to have a particle size of about 0.1 μm to about 40 μm and the filler 13D may be used as a heat transfer path HP. The particle size of the diamond filler DF may be less than the thickness 13T of the adhesive layer 13. More particularly, the particle size of the diamond grains of the diamond filler DF may be less than the thickness 13T of the adhesive layer 13.

In addition, an average particle size of the diamond grains of the diamond filler DF may be greater than an average particle size of the alumina filler AF. The thermal conductivity of the diamond filler DF may be greater than that of the alumina filler AF. In detail, the thermal conductivity of the diamond filler DF may be greater than about 1000 watts per meter kelvin (W/mk), and the thermal conductivity of the alumina filler AF may be about 25 W/mk. A larger average particle size of the diamond grains of the diamond filler DF with a higher thermal conductivity may increase an overall thermal conductivity of the die attach film 10.

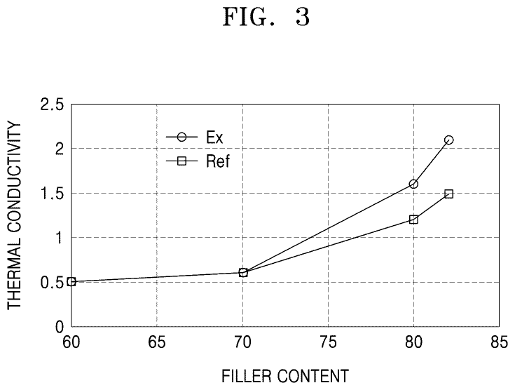

FIG. 3 is a comparative graph illustrating a change in thermal conductivity according to the presence or absence of a diamond filler in the die attach film.

In detail, the first line (Ref) connecting the square shapes is a graph representing a change in thermal conductivity according to a filler content in a die attach film including alumina filler in the adhesive layer and omitting a diamond filler. That is, with respect to 100 parts by weight of filler, the alumina filler may substantially account for 100 parts by weight.

In comparison, the second line (Ex) connecting the circular shapes is a graph representing a change in thermal conductivity according to a filler content in the die attach film in which the alumina filler and the diamond filler are included in the adhesive layer. That is, with respect to 100 parts by weight of filler, the ratio of parts by weight of the alumina filler to parts by weight of the diamond filler may be about 3:1.

Referring to FIG. 3, the graph represents a change in thermal conductivity over filler content in an experimental example (Ex) which corresponds to a die attach film of the inventive concept in which an alumina filler and a diamond filler are included in an adhesive layer and a change in thermal conductivity over filler content in a comparative example (Ref) in which an alumina filler is included in an adhesive layer and a diamond filler is omitted.

When the filler content is about 60 parts by weight to about 70 parts by weight based on 100 parts by weight of the adhesive layer in each of the experimental example Ex and comparative example Ref, a difference in thermal conductivity depending on the presence or absence of the diamond filler is small.

In contrast, when the filler content was about 70 parts by weight to about 83 parts by weight based on 100 parts by weight of the adhesive layer in each of the experimental example Ex and comparative example Ref, a difference in thermal conductivity depending on the presence or absence of the diamond filler increases to about 33% or more. In other words, the inclusion of the diamond filler may significantly improve a thermal conductivity of the adhesive layer as the filler content increases.

Although not restrained by a specific theory, the improvement in thermal conductivity may be due to the characteristic that the alumina filler and the diamond filler in contact with each other, which may form a heat transfer path extending from the top to the bottom of the die attach film.

According to an embodiment, the thermal conductivity may significantly increase due to the formation of the heat transfer path in the die attach film when the content of the alumina filler and the diamond filler in combination is about 70 parts by weight to about 85 parts by weight based on 100 parts by weight of the adhesive layer and the ratio of the parts by weight of the alumina filler to the parts by weight of the diamond filler is about 2:1 to about 3:1.

In addition, when the content of the filler exceeded about 85 parts by weight based on 100 parts by weight of the adhesive layer, an adhesive strength of the adhesive layer may decrease due to the increased content of the filler included in the adhesive layer. According to an embodiment, the function of the die attach film may be maintained if the filler content being below about 85 parts by weight based on 100 parts by weight of the adhesive layer.

FIG. 4A is a schematic cross-sectional view illustrating the semiconductor package 100 according to an embodiment. FIG. 4B is an enlarged cross-sectional view illustrating portion CX of the semiconductor package 100 of FIG. 4A.

Referring to FIG. 4A and FIG. 4B together, the semiconductor package 100 may include a substrate 110, a first semiconductor chip 120, a semiconductor chip stack CS, a molding layer 160, and an external connection terminal 170.

The substrate 110 may be, for example, a printed circuit board (PCB), flexible substrate, wafer substrate, ceramic substrate, or glass substrate.

When the substrate 110 is a PCB, the substrate 110 may include one or more of phenol resin, epoxy resin, or polyimide. For example, the substrate 110 may include FR4, tetrafunctional epoxy, polyphenylene ether, epoxy/polyphenylene oxide, bismaleimidetriazine, thermount, cyanate ester, polyimide, or liquid crystal polymer.

The substrate 110 may include a plurality of lower pads 111 and a plurality of upper pads 113. The lower pads 111 may be provided on a lower surface of the substrate 110. The upper pads 113 may be provided on an upper surface of the substrate 110. The lower pads 111 and the upper pads 113 may be electrically connected to each other through a wiring pattern 115. The wiring pattern 115 may be provided inside the substrate 110. Each of the lower pads 111, the upper pads 113, and the wiring pattern 115 may include a metal, such as aluminum (Al), copper (Cu), tungsten (W), or titanium (Ti).

The semiconductor package 100 may include a plurality of external connection terminals 170. The external connection terminals 170 may be respectively arranged on lower surfaces of the lower pads 111. The external connection terminals 170 may be respectively connected to the lower pads 111. The external connection terminal 170 may be, for example, a solder ball or solder bump. The external connection terminal 170 may include a solder material, such as tin (Sn), silver (Ag), or zinc (Zn), and/or alloys thereof.

The first semiconductor chip 120 may be disposed on an upper surface of the substrate 110. The first semiconductor chip 120 may be disposed in a relatively central region on the upper surface of the substrate 110.

The first semiconductor chip 120 may include a first semiconductor substrate 121. The first semiconductor substrate 121 may include, for example, a semiconductor material, such as silicon (Si) or germanium (Ge), a compound semiconductor material, such as silicon carbide (SIC), gallium arsenide (GaAs), indium arsenide (InAs), or indium phosphide (InP). The first semiconductor substrate 121 may include a conductive region, for example, a well doped with impurities. The first semiconductor substrate 121 may have various device isolation structures, such as a shallow trench isolation (STI) structure.

The first semiconductor substrate 121 may include a first active surface and a first inactive surface disposed opposite to the first active surface. The first active surface may include one or more devices. These devices may be of a same type or of different types. For example, the devices may include various microelectronic devices, for example, a metal-oxide-semiconductor field effect transistor (MOSFET), such as a complementary metal-oxide semiconductor (CMOS) transistor, a system large scale integration (LSI), an image sensor, such as a CMOS image (CIS), a micro-electro-mechanical system (MEMS), an active device, a passive device, or a logic device, such as a central processing unit (CPU), a micro-processing unit (MPU), a graphics processing unit (GPU), an application processor (AP), a microcontroller, or an application-specific integrated chip (ASIC).

A plurality of first connection terminals 123 may be disposed on a lower surface of the first semiconductor chip 120. The first connection terminals 123 may electrically connect the first semiconductor chip 120 to the substrate 110. The first connection terminals 123 may be, for example, solder balls or solder bumps. The first connection terminals 123 may include a solder material, such as tin (Sn), silver (Ag), or zinc (Zn), and/or alloys thereof.

An underfill layer 125 may be disposed in a region between the lower surface of the first semiconductor chip 120 and the upper surface of the substrate 110. The underfill layer 125 may fill the region between the lower surface of the first semiconductor chip 120 and the upper surface of the substrate 110. The underfill layer 125 may surround the first connection terminals 123 arranged on the lower surface of the first semiconductor chip 120. For example, the underfill layer 125 may be an insulating material layer, but is not limited thereto. In some cases, the underfill layer 125 may be omitted, and a molded underfill (MUF) process may be used instead.

A semiconductor chip stack CS may be disposed on the upper surface of the substrate 110. The semiconductor chip stack CS may be spaced apart from the first semiconductor chip 120 on the substrate 110 in the horizontal direction (an X or Y direction). For example, the semiconductor chip stack CS may be disposed in an edge region of the substrate 110 and spaced apart from the first semiconductor chip 120 in the horizontal direction (the X or Y direction).

The semiconductor chip stack CS may include a plurality of second semiconductor chips 130. The plurality of second semiconductor chips 130 may be stacked on the substrate 110 in the vertical direction (a Z direction). The second semiconductor chips 130 included in the semiconductor chip stack CS may be stacked, for example, in a staircase or cascade structure in the horizontal direction (the X or Y direction).

Each of the second semiconductor chips 130 may include a second semiconductor substrate 131. The second semiconductor substrate 131 may include substantially the same material as that of the first semiconductor substrate 121 of the first semiconductor chip 120.

The second semiconductor substrate 131 may include a second active surface 131F and a second inactive surface 131S disposed opposite to the second active surface 131F. One or more devices may be formed on the second active surface 131F of the second semiconductor substrate 131. These devices may be of a same type or different types.

A chip pad 133 may be provided on the second active surface 131F of each of the second semiconductor substrates 131. The chip pad 133 may be disposed adjacent to a side of the second semiconductor substrate 131. For example, the chip pad 133 may be disposed adjacent to a side of the second semiconductor substrate 131 that is relatively distant from the first semiconductor chip 120 in a plan view. The chip pad 133 may include a metal, such as aluminum (Al), copper (Cu), tungsten (W), or titanium (Ti).

A die attach film 140 may be attached to the second inactive surface 131S of each of the second semiconductor chips 130. Here, the die attach film 140 may adhere and fix the semiconductor chip stack CS, the substrate 110, and each of the second semiconductor chips 130 included in the semiconductor chip stack CS. The second semiconductor chips 130 may be stacked in a staircase structure or cascade structure in the horizontal direction (the X or Y direction), and the die attach film 140 may not cover the chip pad 133 of each of the second semiconductor chips 130.

In some embodiments, the die attach film 140 may extend laterally and protrude from a side of each of the second semiconductor chips 130. Referring to FIG. 4B, the die attach film 140 may include an adhesive layer 141 and a filler 143. Here, the adhesive layer 141 and the filler 143 of the die attach film 140 may correspond to the adhesive layer 13 and the filler 13D of the die attach film 10 described herein with reference to FIG. 1 and FIG. 2.

In some embodiments, the semiconductor chip stack CS may be disposed on the first semiconductor chip 120. In this case, the second semiconductor chips 130 of the semiconductor chip stack CS may be stacked on the first semiconductor chip 120 in the vertical direction (the Z direction), and the lowermost second semiconductor chips 130 among the second semiconductor chips 130 may be bonded and fixed to the first semiconductor chip 120 by the die attach film 140 formed on the second inactive surface 131S of the lowermost second semiconductor chip 130.

The first semiconductor chip 120 and the second semiconductor chip 130 may be memory chips and/or logic chips. For example, the first semiconductor chip 120 may be a logic chip, and the second semiconductor chip 130 may be a memory chip. The memory chip may be, for example, a volatile memory chip, such as dynamic random access memory (DRAM) or static random access memory (SRAM), or a nonvolatile memory chip, such as phase-change random access memory (PRAM), magnetoresistive random access memory (MRAM), ferroelectric random access memory (FeRAM), or resistive random access memory (RRAM). In addition, the logic chip may be, for example, a microprocessor, an analog device, or a digital signal processor.

In some embodiments, the first semiconductor chip 120 and the second semiconductor chip 130 may be the same type of semiconductor chip. For example, both the first semiconductor chip 120 and the second semiconductor chip 130 may be memory chips. In other embodiments, the first semiconductor chip 120 and the second semiconductor chip 130 may be different types of semiconductor chips. For example, the first semiconductor chip 120 may be a logic chip, and the second semiconductor chip 130 may be a memory chip.

A bonding wire 150 may be attached to the chip pad 133 of each of the second semiconductor chips 130. The bonding wire 150 may connect the chip pad 133 of the second semiconductor chip 130 to the upper pad 113 of the substrate 110, or connect the chip pads 133 of the second semiconductor chips 130 to each other. Accordingly, the second semiconductor chips 130 and the substrate 110 or the second semiconductor chips 130 may be electrically connected to each other through the bonding wires 150. For example, the bonding wire 150 may include at least one of gold (Au), silver (Ag), copper (Cu), or aluminum (Al).

At least one of a control signal, a power signal, or a ground signal for an operation of the second semiconductor chips 130 may be provided from the outside through the bonding wire 150. In addition, a data signal to be stored in the second semiconductor chips 130 may be provided from an external source through the bonding wire 150, or data stored in the second semiconductor chips 130 may be provided externally.

A molding layer 160 may be formed on the substrate 110. The molding layer 160 may cover the first semiconductor chip 120, the second semiconductor chips 130, and the bonding wire 150. The molding layer 160 may include, for example, an epoxy molding compound.

In some embodiments, side and upper surfaces of the molding layer 160 may be disposed at right angles to each other. Although not shown, a marking pattern, for example, a barcode, QR code, numbers, letters, symbols, etc. including information on the semiconductor package 100 may be formed on the side and/or upper surface of the molding layer 160.

In some embodiments, the molding layer 160 may protect one or more of the first semiconductor chip 120, the second semiconductor chips 130, or the bonding wire 150. For example, the molding layer 160 may protect the first semiconductor chip 120, the second semiconductor chips 130, and the bonding wire 150 from external influences, such as contamination and impact. In order to perform the role, the thickness of the molding layer 160 may be formed to surround the first semiconductor chip 120, the second semiconductor chips 130, and the bonding wire 150. In a case that the molding layer 160 covers the entire substrate 110, the width of the molding layer 160 may be substantially equal to the width of the semiconductor package 100.

The semiconductor package 100 according to the inventive concept may include the semiconductor chip stack CS including the second semiconductor chips 130, and the die attach film 140 including the adhesive layer 141 and the filler 143 dispersed in the adhesive layer 141 and having improved heat dissipation characteristics. The adhesive layer 141, including the filler 143, may be provided between each of the second semiconductor chips 130.

In the die attach film 140 according to the inventive concept, the filler 143 may be used as the heat transfer path HP. Each die attach film 140 may function as a heat dissipation plate between the second semiconductor chips 130. To this end, the filler 143 in the die attach film 140 may include a material having heat dissipation characteristics. The filler 143 may include different types of fillers dispersed in the adhesive layer 141. For example, the filler 143 may include the alumina filler AF and the diamond filler DF.

In some embodiments, the content of the filler 143 may be about 70 parts by weight to about 85 parts by weight based on 100 parts by weight of the adhesive layer 141 and the heat dissipation characteristics of the die attach film 140 may be improved. In addition, in the filler 143, the ratio of parts by weight of the alumina filler AF to parts by weight of the diamond filler DF may be about 2:1 to about 3:1. That is, the parts by weight of the alumina filler AF may be relatively greater than the parts by weight of the diamond filler DF.

In some embodiments, the diamond filler DF may be provided in the form of powder dispersed in the adhesive layer 13 and the heat dissipation characteristics of the die attach film 140 may be improved. The diamond filler DF may have a surface treated with a silane coupling agent.

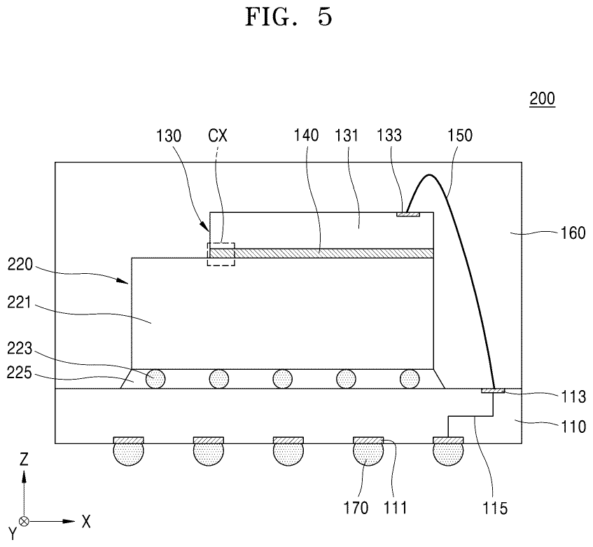

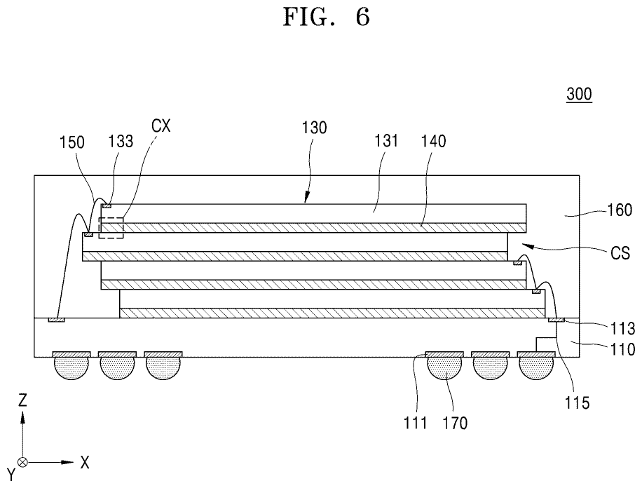

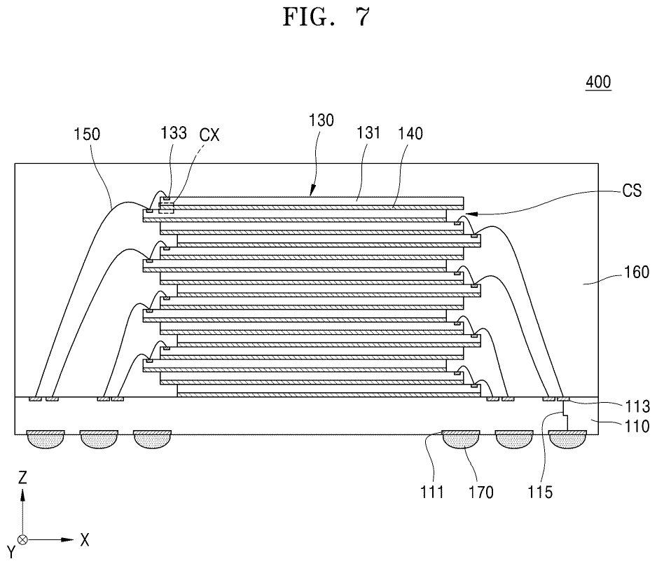

FIG. 5, FIG. 6, and FIG. 7 are cross-sectional views respectively illustrating semiconductor packages 200, 300, and 400 according to other embodiments.

Some of the components constituting the semiconductor packages 200, 300, and 400 described below and the materials forming the components may be substantially the same as or similar to those described herein with reference to FIG. 4A and FIG. 4B. Therefore, for convenience of description, differences of the semiconductor packages 200, 300, and 400 from the semiconductor package 100 are mainly described, and repetitive descriptions may be omitted.

In addition, the portion CX of the semiconductor packages 200, 300, and 400 of FIG. 5, FIG. 6, and FIG. 7 is substantially the same as the portion CX of FIG. 4B, so repetitive descriptions thereof may be omitted here.

Referring to FIG. 5, the semiconductor package 200 may include the substrate 110, a first semiconductor chip 220, the second semiconductor chip 130, the bonding wire 150, and the molding layer 160.

In an embodiment, the first semiconductor chip 220 may be disposed on the upper surface of the substrate 110. The first semiconductor chip 220 may be disposed in a relatively central region of the upper surface of the substrate 110. The first semiconductor chip 220 may include a first semiconductor substrate 221. A plurality of first connection terminals 223 may be disposed on a lower surface of the first semiconductor chip 220. The first connection terminals 223 may be arranged in a region between the lower surface of the first semiconductor chip 220 and the upper surface of the substrate 110. An underfill layer 225 may be disposed in the region between the lower surface of the first semiconductor chip 220 and the upper surface of the substrate 110. The underfill layer 225 may surround first connection terminals 223 disposed between the lower surface of the first semiconductor chip 220 and the upper surface of the substrate 110. The underfill layer 225 may fill the region between the lower surface of the first semiconductor chip 220 and the upper surface of the substrate 110.

In an embodiment, the second semiconductor chip 130 may be attached to the upper surface of the first semiconductor chip 220 through the die attach film 140. The die attach film 140 may include the adhesive layer 141 (see FIG. 4B) and the filler 143 (see FIG. 4B). Here, the adhesive layer 141 (see FIG. 4B) and the filler 143 (see FIG. 4B) of the die attach film 140 may correspond to the adhesive layer 13 and the filler 13D of the die attach film 10 described above with reference to FIG. 1 and FIG. 2.

In an embodiment, the first semiconductor chip 220 may be, for example, a modem chip. That is, the first semiconductor chip 220 may perform wired and/or wireless communication functions. In addition, the second semiconductor chip 130 may be, for example, a DRAM memory chip. However, the semiconductor package 200 of the inventive concept is not limited thereto.

Referring to FIG. 6, the semiconductor package 300 may include the substrate 110, the semiconductor chip stack CS, the bonding wire 150, and the molding layer 160.

In an embodiment, the semiconductor chip stack CS may include the second semiconductor chips 130 stacked on the substrate 110 in the vertical direction (the Z direction). The second semiconductor chips 130 included in the semiconductor chip stack CS may be stacked in, for example, a cascade structure in the horizontal direction (the X or Y direction).

Although not shown, a plurality of different second semiconductor chips 130 may be disposed side by side in the horizontal direction (the X or Y direction) of the second semiconductor chips 130.

In an embodiment, the second semiconductor chips 130 may be stacked in, for example, a staircase structure or cascade structure in the horizontal direction (the X or Y direction), and the die attach film 140 may not cover the chip pad 133 of each of the second semiconductor chips 130. For example, the chip pads 133 may be exposed at upper surfaces of the second semiconductor chips 130.

In an embodiment, the die attach film 140 may extend laterally and may protrude from the side of each of the second semiconductor chips 130. For example, the die attach film 140 may be exposed on lower surfaces of the second semiconductor chips 130. The die attach film 140 may include the adhesive layer 141 (see FIG. 4B) and the filler 143 (see FIG. 4B). Here, the adhesive layer 141 (see FIG. 4B) and the filler 143 (see FIG. 4B) of the die attach film 140 may correspond to the adhesive layer 13 and the filler 13D of the die attach film 10 described above with reference to FIG. 1 and FIG. 2.

In an embodiment, the bonding wires 150 may be attached to the chip pads 133 of the second semiconductor chips 130. The bonding wires 150 may connect the chip pad 133 of the second semiconductor chip 130 to the upper pad 113 of the substrate 110 or connect the chip pads 133 of the second semiconductor chips 130 to each other. The bonding wire 150 may be located on both sides of one or more of the second semiconductor chips 130.

In an embodiment, each of the second semiconductor chips 130 may be, for example, a mobile DRAM memory chip. However, the semiconductor package 300 of the inventive concept is not limited thereto.

Referring to FIG. 7, the semiconductor package 400 may include the substrate 110, the semiconductor chip stack CS, the bonding wire 150, and the molding layer 160.

In an embodiment, the semiconductor chip stack CS may include sixteen second semiconductor chips 130 stacked on the substrate 110 in the vertical direction (the Z direction). The sixteen second semiconductor chips 130 included in the semiconductor chip stack CS may be stacked in, for example, a cascade structure in the horizontal direction (the X or Y direction).

Although not shown, another sixteen second semiconductor chips 130 may be arranged side by side in the horizontal direction (the X or Y direction) of the sixteen second semiconductor chips 130. That is, the semiconductor package 400 may include a semiconductor chip stack CS including a total of thirty two second semiconductor chips 130 but is not limited thereto.

In an embodiment, the sixteen second semiconductor chips 130 may be stacked in, for example, the cascade structure in the horizontal direction (the X or Y direction), and the chip pad 133 of each of the sixteen second semiconductor chips 130 may be exposed by the die attach film 140.

In an embodiment, the die attach film 140 may extend laterally and protrude from a side surface of each of the sixteen second semiconductor chips 130. The die attach film 140 may include the adhesive layer 141 (see FIG. 4B) and the filler 143 (see FIG. 4B). Here, the adhesive layer 141 (see FIG. 4B) and the filler 143 (see FIG. 4B) of the die attach film 140 may correspond to the adhesive layer 13 and the filler 13D of the die attach film 10 described above with reference to FIG. 1 and FIG. 2.

In an embodiment, the bonding wires 150 may be attached to the chip pad s133 of the sixteen second semiconductor chips 130. The bonding wires 150 may connect the chip pads 133 of the sixteen second semiconductor chips 130 to the upper pad 113 of the substrate 110 or connect the chip pads 133 of the sixteen second semiconductor chips 130 to each other. The bonding wires 150 may be located on one or more sides of the sixteen second semiconductor chips 130.

In an embodiment, each of the sixteen second semiconductor chips 130 may be, for example, a mobile DRAM memory chip. However, the semiconductor package 400 of the inventive concept is not limited thereto.

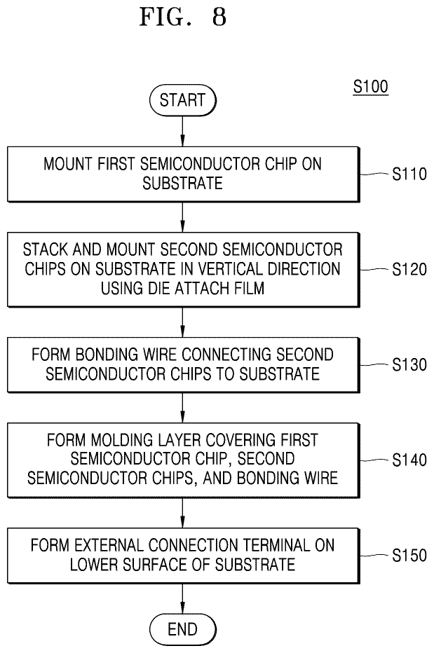

FIG. 8 is a flowchart illustrating a method (S100) of manufacturing a semiconductor package according to an embodiment.

Referring to FIG. 8, a method (S100) of manufacturing a semiconductor package may include a process sequence including a first operation (S110), a second operation (S120), a third operation (S130), a fourth operation (S140), and a fifth operation (S150).

In a case in which an embodiment may be implemented differently, a certain process sequence may be performed differently from the described sequence. For example, two processes described in succession may be performed substantially at the same time or may be performed in an order opposite to the order in which they are described.

A method (S100) of manufacturing a semiconductor package according to the inventive concept may include a first operation (S110) of mounting a first semiconductor chip on a substrate, a second operation (S120) of stacking and mounting a plurality of second semiconductor chips on the substrate using a die attach film in a vertical direction, a third operation (S130) of forming a bonding wire connecting the second semiconductor chips to the substrate, a fourth operation (S140) of forming a molding layer covering the first semiconductor chip, the second semiconductor chips, and the bonding wire, and a fifth operation (S150) of forming an external connection terminal on a lower surface of the substrate.

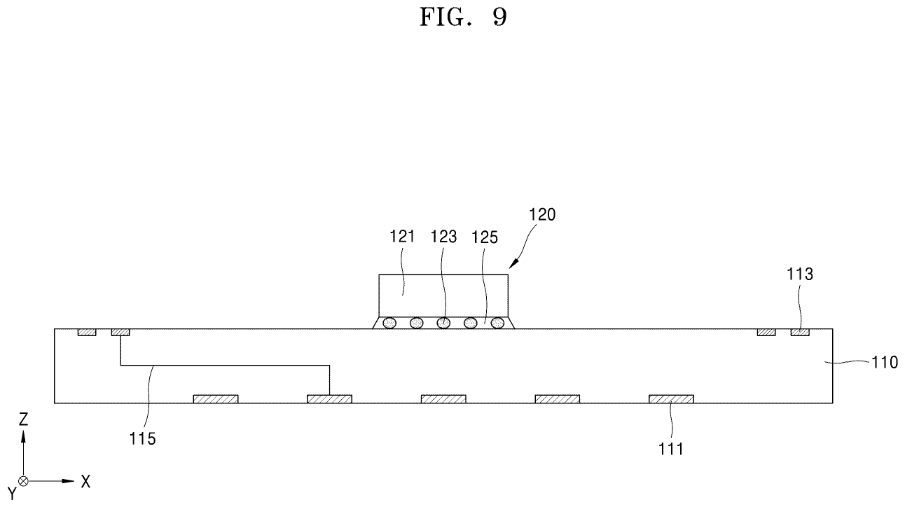

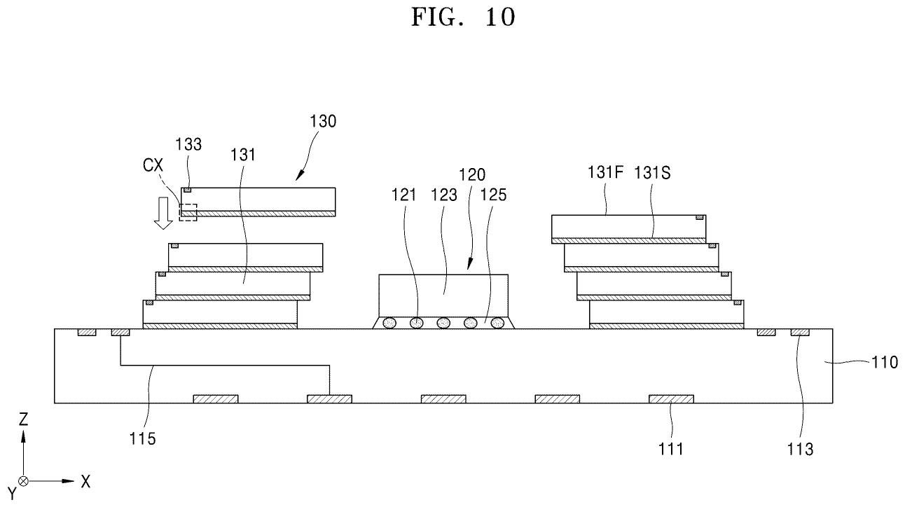

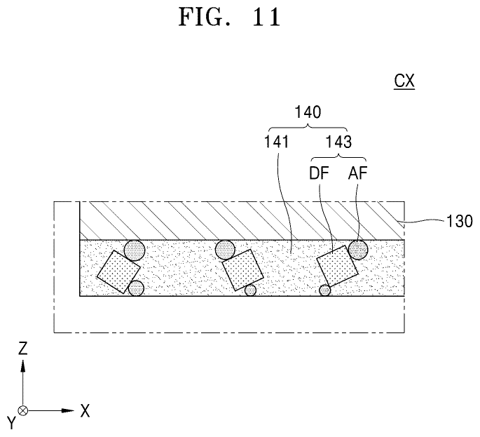

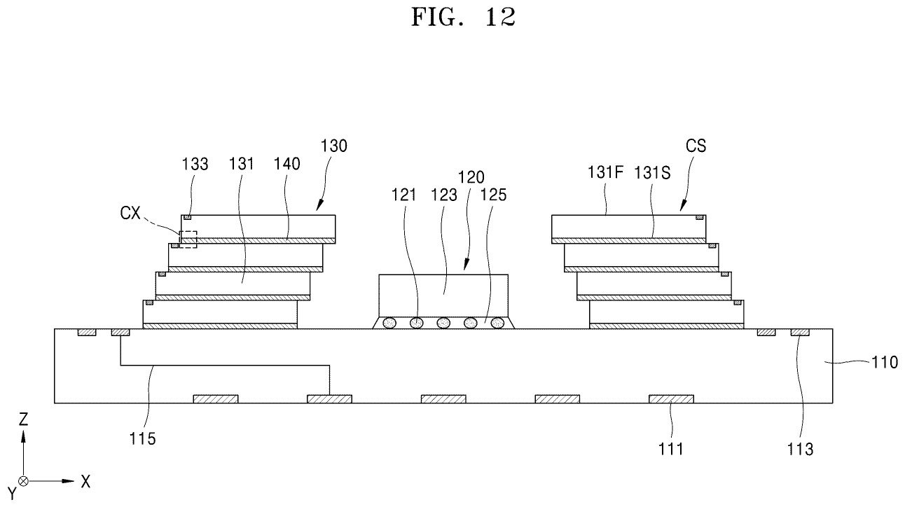

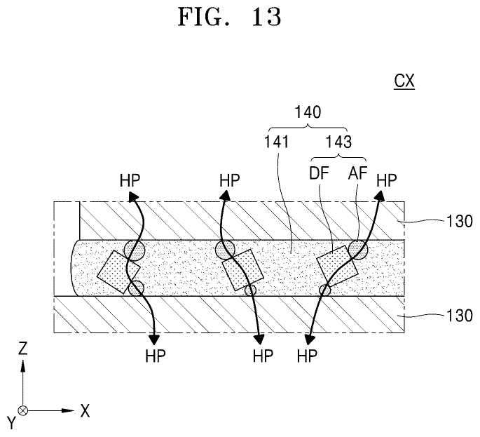

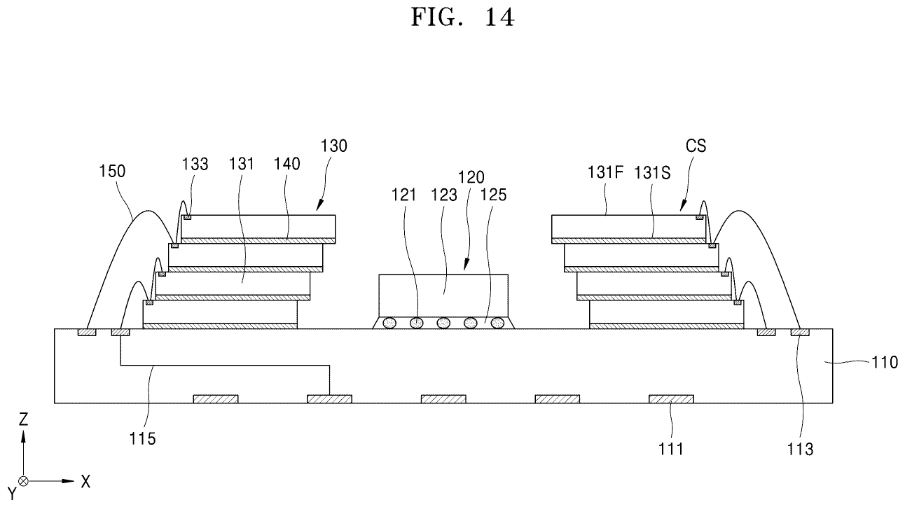

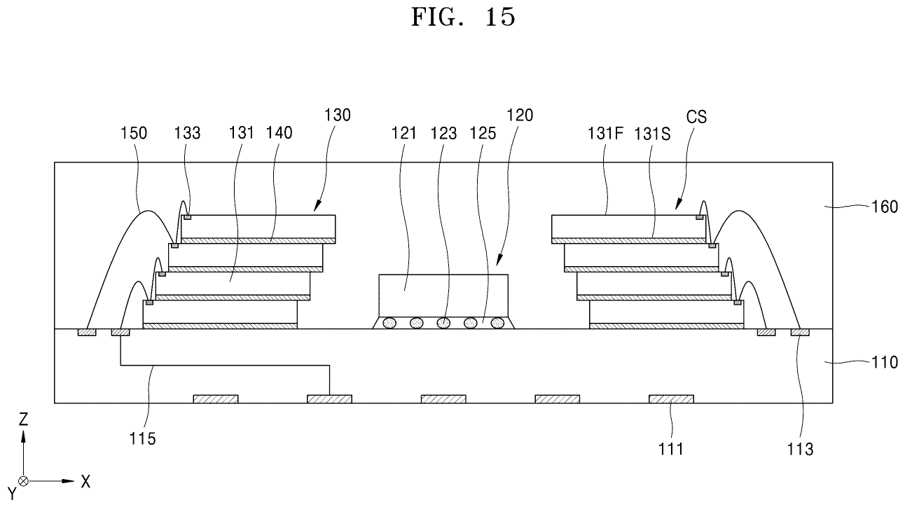

Technical features of each of the first to fifth operations (S110 to S150) are described in detail with reference to FIG. 9, FIG. 10, FIG. 11, FIG. 12, FIG. 13, FIG. 14, and FIG. 15.

FIGS. 9 to 15 are cross-sectional views illustrating a method of manufacturing a semiconductor package according to an embodiment.

Referring to FIG. 9, the first semiconductor chip 120 may be mounted in a central region of the substrate 110.

In some embodiments, the first semiconductor chip 120 with the first connection terminal 123 disposed on the lower surface thereof may be mounted in the center region of the substrate 110. Here, the substrate 110 may be, for example, a printed circuit board.

In some embodiments, the underfill layer 125 may be disposed a space between the lower surface of the first semiconductor chip 120 and an upper surface of the substrate 110. The underfill layer 125 may be formed to surround the first connection terminals 123 disposed on the lower surface of the first semiconductor chip 120. For example, the underfill layer 125 may fill the space between the lower surface of the first semiconductor chip 120 and an upper surface of the substrate 110.

Referring to FIG. 10 and FIG. 11 together, the second semiconductor chips 130 may be stacked on the substrate 110 in the vertical direction (the Z direction) to form the semiconductor chip stack CS spaced apart from the first semiconductor chip 120 in the horizontal direction (the X or Y direction).

In some embodiments, the die attach film 140 may be attached to the lower surface of the second semiconductor substrate 131 included in each of the second semiconductor chips 130. The lower surface of the second semiconductor substrate 131, as an inactive surface, may correspond to the second inactive surface 131S of each of the second semiconductor substrates 131.

Here, the die attach film 140 may include the adhesive layer 141 with the filler 143 dispersed therein. The adhesive layer 141 and the filler 143 may be mixed to form the die attach film 140 as an adhesive composition. The die attach film 140 may be attached on the lower surface of the second semiconductor substrate 131 through a lamination process.

In some embodiments, the second semiconductor chips 130 may formed from one or more wafers. The second semiconductor chips 130 of a wafer may be singulated, and the second semiconductor chips 130 on which the die attach film 140 is attached to the second inactive surface 131S may be provided. The die attach film 140 may be provided on the lower surface of the second semiconductor substrate 131 before or after singulation.

In some embodiments, each of the second semiconductor chips 130 on which the die attach film 140 is attached to the second inactive surface 131S may be stacked in the vertical direction (the Z direction) to form one semiconductor chip stack CS. The process of forming a semiconductor chip stack CS is described herein.

In some embodiments, a lower second semiconductor chip 130 may be disposed in the edge region of the substrate 110 spaced apart from the first semiconductor chip 120 in the horizontal direction (the X or Y direction), and the lower second semiconductor chip 130 may be bonded and fixed to the substrate 110 using the die attach film 140 by performing a thermocompression process.

In some embodiments, an upper one of the second semiconductor chips 130 may be disposed on the lower one of the second semiconductor chips 130 disposed in the edge region of the substrate 110. Here, the upper one of the second semiconductor chips 130 may be disposed on the lower one of the second semiconductor chips 130 to form a staircase or cascade structure in the horizontal direction (the X or Y direction) with the one second semiconductor chip 130.

In some embodiments, the upper one of the second semiconductor chips 130 may be bonded and fixed to the lower one of the second semiconductor chips 130 through the die attach film 140 by performing a thermocompression process.

Referring to FIG. 12 and FIG. 13 together, the semiconductor chip stack CS including the second semiconductor chips 130 may be formed on one or more edges of the substrate 110 by repeatedly performing the aforementioned stacking process of the second semiconductor chips 130. That is, one or more additional second semiconductor chips 130 may be disposed on the upper one of the second semiconductor chips 130.

In some embodiments, in the stacking process of the second semiconductor chips 130, the die attach film 140 may be compressed by performing a thermocompression process. Accordingly, the die attach film 140 in the semiconductor chip stack CS may protrude to extend laterally from the side of the second semiconductor chip 130, as shown in FIG. 13.

In addition, in the die attach film 140, the filler 143 may be used as the heat transfer path HP. That is, in the die attach film 140, the filler 143 may include a material having heat dissipation characteristics. To this end, the filler 143 may include different types of fillers dispersed in the adhesive layer 141. That is, the filler 143 may include, for example, the alumina filler AF and the diamond filler DF.

Referring to FIG. 14, the bonding wires 150 connecting the chip pads 133 of the second semiconductor chips 130 to the upper pad 113 of the substrate 110 may be formed.

The bonding wires 150 may be connected to the chip pads 133 of the second semiconductor chips 130 and the upper pad 113 of the substrate 110 by, for example, a thermocompression connection method or ultrasonic connection method, or may be connected thereto by a thermosonic connection method that combines the thermocompression connection method and the ultrasonic connection method.

Referring to FIG. 15, the molding layer 160 may be disposed on the first semiconductor chip 120, the semiconductor chip stacks CS, and the bonding wire 150.

The molding layer 160 may be formed by injecting an appropriate amount of molding material onto the substrate 110 through an injection process and may form an outer shape of the semiconductor package 100 through a curing process. In some embodiments, the outer shape of the semiconductor package 100 may be formed by applying pressure to the molding material in a pressing process, such as a press.

Here, process conditions, such as a delay time between injection of the molding material and pressing, the amount of the injected molding material, and a pressing temperature/pressure may be set in consideration of physical properties, such as viscosity of the molding material.

Referring again to FIG. 4A, the semiconductor package 100 may be manufactured by forming the external connection terminal 170 on the lower pad 111 of the substrate 110 in a resulting structure of FIG. 15.

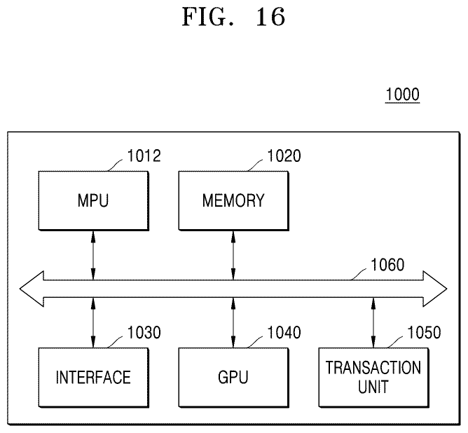

FIG. 16 is a diagram schematically illustrating a configuration of a semiconductor package 1000 according to some embodiments.

Referring to FIG. 16, the semiconductor package 1000 may include a microprocessing unit (MPU) 1012, a memory 1020, an interface 1030, a GPU 1040, functional blocks (e.g., a transaction unit, etc.) 1050, and a bus 1060 connecting these components to each other.

The semiconductor package 1000 may include one or more of the MPU 1012 or the GPU 1040.

The MPU 1012 may include a core and a cache. For example, the MPU 1012 may include multiple cores. Each of the multiple cores may have the same or different performance. In addition, the multiple cores may be activated at the same time or may be activated at different times.

The memory 1020 may store processing results from the functional blocks 1050 under control of the MPU 1012. The interface 1030 may exchange information or signals with external devices. The GPU 1040 may perform graphics functions. For example, the GPU 1040 may perform video codec or process 3D graphics. The functional blocks 1050 may perform various functions. For example, when the semiconductor package 1000 is an application processor used in a mobile device, some of the functional blocks 1050 may perform a communication function.

The semiconductor package 1000 may include at least one of the semiconductor packages 100, 200, 300, and 400 described above.

While the inventive concept has been particularly shown and described with reference to embodiments thereof, it will be understood that various changes in form and details may be made therein without departing from the spirit and scope of the following claims.

What is claimed is:

1. A die attach film comprising:
an adhesive layer;
an alumina filler disposed in the adhesive layer; and
a diamond filler disposed in the adhesive layer,
wherein a content of the alumina filler and the diamond filler in combination is about 70 parts by weight to about 85 parts by weight based on 100 parts by weight of the adhesive layer, and
a ratio of parts by weight of the alumina filler to parts by weight of the diamond filler is about 2:1 to about 3:1.

2. The die attach film of claim 1, wherein the diamond filler comprises a plurality of diamond grains, and the diamond grains have a polyhedron shape, and surfaces of the diamond grains are treated with a silane coupling agent.

3. The die attach film of claim 1, wherein
a thickness of the adhesive layer is about 5 μm to about 100 μm,
a particle size of the diamond filler is about 0.1 μm to about 40 μm, and
a particle size of the diamond filler is less than the thickness of the adhesive layer.

4. The die attach film of claim 3, wherein an average particle size of a plurality of diamond grains of the diamond filler is greater than an average particle size of the alumina filler.

5. The die attach film of claim 1, wherein a thermal conductivity of the diamond filler is greater than about 1,000 watts per meter kelvin.

6. The die attach film of claim 1, wherein
the adhesive layer further includes a binding polymer, and
the binding polymer is a thermoplastic polymer including an acrylic polymer.

7. The die attach film of claim 6, wherein
the adhesive layer further includes a thermosetting resin, and
the thermosetting resin includes a bifunctional thermosetting resin comprising at least one of bisphenol A-type, bisphenol F-type, bisphenol S-type, brominated bisphenol A-type, hydrogenated bisphenol A-type, bisphenol AF-type, and biphenyl type, or a multifunctional thermosetting resin.

8. The die attach film of claim 7, wherein
the adhesive layer further includes a curing agent, and
the curing agent comprises at least one of a phenol novolak resin, a phenol aralkyl resin, a cresol novolak resin, or a tert-butylphenol novolak resin.

9. The die attach film of claim 8, wherein
the adhesive layer further includes an additive, and
the additive includes at least one of a curing rate controlling agent, an interfacial adhesion improver, an oxidation stabilizer, or an ion capturing agent.

10. The die attach film of claim 9, wherein,
with respect to 100 parts by weight of the adhesive layer,
the alumina filler and the diamond filler are, in combination, about 80 parts by weight,
the binding polymer is about 10 parts by weight, and
the thermosetting resin, the curing agent, and the additive, in combination, are about 10 parts by weight.

11. A die attach film comprising:
a first base film;
an adhesive layer disposed on the first base film;
a pressure sensitive adhesive layer disposed on the adhesive layer; and
a second base film disposed on the pressure sensitive adhesive layer,
wherein the adhesive layer includes a binding polymer, a thermosetting resin, a curing agent, a filler, and an additive,
wherein the filler includes an alumina filler and a diamond filler,
a content of the alumina filler and the diamond filler in combination is about 70 parts by weight to about 85 parts by weight based on 100 parts by weight of the adhesive layer, and
a ratio of parts by weight of the alumina filler to parts by weight of the diamond filler is about 2:1 to about 3:1.

12. The die attach film of claim 11, wherein
a thickness of the first base film is about 35 micrometers (μm) to about 40 μm,
a thickness of the adhesive layer is about 5 μm to about 100 μm,
a thickness of the pressure sensitive adhesive layer is about 5 μm to about 30 μm,
a thickness of the second base film is about 80 μm to about 100 μm,
a particle size of the diamond filler dispersed in the adhesive layer is about 0.1 μm to about 40 μm, and
the particle size of the diamond filler is less than the thickness of the adhesive layer.

13. The die attach film of claim 12, wherein
the first base film includes polyethylene terephthalate (PET), and
the second base film includes polyolefin (PO).

14. The die attach film of claim 11, wherein
the diamond filler comprises a plurality of diamond grains, and the diamond grains have a polyhedron shape having a surface treated with a silane coupling agent, and
a thermal conductivity of the diamond filler is greater than about 1,000 watts per meter kelvin.

15. The die attach film of claim 11, wherein
a thermal conductivity of the diamond filler is greater than a thermal conductivity of the alumina filler, and
an average particle size of the diamond filler is greater than an average particle size of the alumina filler.

16. A semiconductor package comprising:
a substrate;
a first semiconductor chip disposed on the substrate;
a semiconductor chip stack disposed on the substrate horizontally spaced apart from the first semiconductor chip and including a plurality of second semiconductor chips
stacked in a vertical direction;
a bonding wire connecting the substrate to the semiconductor chip stack; and
a plurality of die attach films respectively disposed on lower surfaces of the plurality of second semiconductor chips of the semiconductor chip stack,
wherein each of the plurality of die attach films comprises:
an adhesive layer;
an alumina filler dispersed in the adhesive layer; and
a diamond filler dispersed in the adhesive layer,
wherein a content of the alumina filler and the diamond filler in combination is about 70 parts by weight to about 85 parts by weight based on 100 parts by weight of the adhesive layer, and
a ratio of parts by weight of the alumina filler to parts by weight of the diamond filler is about 2:1 to about 3:1.

17. The semiconductor package of claim 16, wherein
a thickness of the adhesive layer is about 5 μm to about 100 μm,
the diamond filler comprises a plurality of diamond grains, and the diamond grains have a polyhedron shape having a surface treated with a silane coupling agent and a particle size of about 0.1 μm to about 40 μm, and
the particle size of the diamond grains of the diamond filler is less than a thickness of the adhesive layer.

18. The semiconductor package of claim 17, wherein
a thermal conductivity of the alumina filler is about 25 watts per meter kelvin (W/mk),
a thermal conductivity of the diamond filler is greater than about 1,000 W/mk, and
a thermal conductivity of the adhesive layer is greater than about 3 W/mk.

19. The semiconductor package of claim 18, wherein the plurality of die attach films form a heat dissipation plate disposed between the plurality of second semiconductor chips stacked in the semiconductor chip stack.

20. The semiconductor package of claim 16, wherein
the adhesive layer includes a binding polymer, a thermosetting resin, a curing agent, a filler, and an additive, and
with respect to 100 parts by weight of the adhesive layer, the alumina filler and the diamond filler are, in combination, about 80 parts by weight, the binding polymer is about 10 parts by weight, and the thermosetting resin, the curing agent, and the additive are, in combination, about 10 parts by weight.
